(19) United States
(12) Patent Application Publication
(10) Pub. No.: US 2026/0210777 A1
(43) Pub. Date: Jul. 23, 2026

(54) MEASURING SYSTEM

(71) Applicant: TOPOLOGIC INC., Tokyo (JP)

(72) Inventor: Arata TAKAHASHI, Tokyo (JP)

(21) Appl. No.: 19/142,677

(22) PCT Filed: Dec. 21, 2023
(86) PCT No.: PCT/JP2023/045899

§ 371 Date: Jun. 24, 2025

(30) Foreign Application Priority Data
Dec. 28, 2022 (JP) 2022-212371

(51) Int. Cl. G01K 17/00

(52) U.S. Cl. CPC G01K 17/00

(57) ABSTRACT

An embodiment of the present invention provides a measuring system. The measuring system comprises a heat flow sensor and a housing. The heat flow sensor comprises an electrically insulating substrate and a thermoelectric conversion part that is provided on the substrate. The thermoelectric conversion part is configured so that an electromotive force occurs on the basis of a temperature gradient along a gradient direction that is the direction from the substrate to the thermoelectric conversion part. The housing is configured to be capable of accommodating the heat flow sensor, and comprises a first wall part and a second wall part. The first wall part is configured so as to exchange heat with the thermoelectric conversion part via the substrate. The second wall part is configured so as to exchange heat with the thermoelectric conversion part not via the same substrate or a different substrate.

### CROSS REFERENCE TO RELATED APPLICATIONS

This application is a 371 U.S. National Phase of International Application No. PCT/JP 2023/045899, filed on Dec. 21, 2023, which claims priority to Japanese Patent Application No. 2022-212371, filed Dec. 28, 2022. The entire disclosures of the above applications are incorporated herein by reference.

### BACKGROUND

### Technical Field

The present invention relates to a measuring system.

### Background Art

Japanese Unexamined Patent Application Publication No. 2019-132802 discloses a technology related to a heat flux sensor capable of accurately measuring the amount of the physiological heat of a person to be measured while suppressing discomfort of the person to be measured.

This heat flux sensor for measuring the amount of heat emitted from a human body or a heat flux received by a human body includes a porous film and a thermocouple array circuit. The porous film is formed in the shape of a thin sheet and has a continuous pore porous structure in which a large number of pores are continuously connected to each other from one surface to the other surface in the thickness direction. The thermocouple array circuit is disposed inside the porous film and outputs a sensor signal corresponding to a heat flux passing through the porous film in the thickness direction.

There is still room for improvement in the technology for practically incorporating a thermoelectric conversion unit such as the above heat flux sensor into a measuring system.

### SUMMARY

According to one aspect of the present invention, a measuring system is provided. This measuring system includes a heat flow sensor and a housing. The heat flow sensor includes a substrate having electrical insulation properties and a thermoelectric conversion unit disposed on the substrate. The thermoelectric conversion unit is configured to generate an electromotive force on the basis of a temperature gradient along a gradient direction that is a direction from the substrate toward the thermoelectric conversion unit. The housing houses the heat flow sensor and includes a first wall and a second wall. The first wall is configured to exchange heat with the thermoelectric conversion unit through the substrate. The second wall is configured to exchange heat with the thermoelectric conversion unit not through the substrate or a substrate different from the substrate.

Such a configuration can promote practical use of measuring systems including a thermoelectric conversion unit.

### BRIEF DESCRIPTION OF THE DRAWINGS

FIG. 1 is an overall perspective view showing an example configuration of a measuring system 1.

FIG. 2 is a cross-sectional view of a surface having an x-axis direction as the normal direction of the measuring system 1 shown in FIG. 1.

FIG. 3 is a diagram showing an example configuration of the measuring system 1 where an integrated circuit 32 as an example of a device is disposed on an exposed portion E1.

FIG. 4 is a diagram showing an example configuration of a thermoelectric conversion unit 51.

FIG. 5 is a diagram showing an example configuration of a thermoelectric conversion device 5 including multiple thermoelectric conversion units 51.

FIG. 6 is a diagram showing an example of a measuring system 1 without a signal processing unit 3.

### DETAILED DESCRIPTION

Now, a preferred embodiment of the present disclosure will be described in detail with reference to the accompanying drawings. In the present specification and drawings, components having substantially the same functional configuration are given the same reference signs and will not repeatedly be described.

A program to implement software in the present embodiment may be provided as a computer-readable non-transitory storage medium, or may be provided by download from an external server. The program may also be provided such that it is run on an external computer and its functions are implemented on a client terminal (so-called cloud computing).

The term “unit” in the present embodiment includes, for example, a combination of hardware resources implemented by a circuit in a broad sense and software information processing that can be specifically performed by the hardware resources. Various types of information handled in the present embodiment are represented by, for example, the physical values of signal values representing voltages or currents, high or low signal values as binary bit sets consisting of 0 s or 1 s, or quantum superpositions (so-called qubits) and can be transmitted and subjected to a calculation on a circuit in a broad sense.

The term “circuit in a broad sense” refers to a circuit implemented by combining at least a circuit, circuitry, a processor, memory, and the like appropriately. Specifically, the term “circuit in a broad sense” includes an application-specific integrated circuit (ASIC), programmable logic devices (e.g., a simple programmable logic device (SPLD), a complex programmable logic device (CPLD), a field programmable gate array (FPGA)), and the like.

### 1. Example Configuration of Measuring System 1

This section describes an example configuration of a measuring system 1.

### 1.1. Overview of Measuring System 1

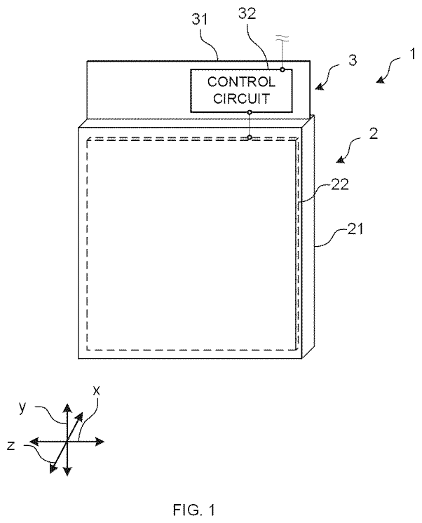

FIG. 1 is an overall perspective view of an example configuration of the measuring system 1. The scale, the positional relationship, and the like are only illustrative, and these are not limiting. As shown in FIG. 1, the measuring system 1 includes a measuring unit 2 and a signal processing unit 3.

### Measuring Unit 2

The measuring unit 2 is configured to output an electromotive force on the basis of a temperature gradient along a z-axis direction, which is an example of a gradient direction. The measuring unit 2 according to the present embodiment is formed as a film or plate that spreads in a plane having the z-axis direction, which is an example of the gradient direction, as the normal direction. Hereafter, for convenience's sake, in-plane directions defining the plane perpendicular to the z-axis direction are referred to as x-axis and y-axis directions. The x-axis, y-axis, and z-axis directions are perpendicular to each other. The measuring unit 2 according to the present embodiment includes a housing 21 and a heat flow sensor 22.

### Housing 21

The housing 21 houses the heat flow sensor 22 (to be discussed later). The housing 21 may have any shape. For example, it has a rectangular parallelepiped shape. Although the housing 21 may be made of any material, it is preferably made of a material having relatively low thermal resistance and heat capacity so that it can transfer heat to the heat flow sensor 22 with a short delay. For example, the material of the housing 21 may be a metal, carbon, or the like.

### Heat Flow Sensor 22

The heat flow sensor 22 is configured to output an electromotive force on the basis of a temperature gradient along the z-axis direction. The heat flow sensor 22 is housed inside the housing 21 such that it is electrically insulated from the housing 21.

### Signal Processing Unit 3

The signal processing unit 3 is configured to process signals outputted from the measuring unit 2 and includes a control board 31 and an integrated circuit 32.

### Control Board 31

The control board 31 is connected to at least a portion of the measuring unit 2, for example, the housing 21 and is configured to transmit signals from the heat flow sensor 22. In the present embodiment, the control board 31 is exposed to the outside of the housing 21. For this reason, the control board 31 is preferably a flexible board that can be elastically deformed with respect to at least an external force in the z-axis direction. This reduces the possibility that the control board 31 can be damaged by external interference.

### Integrated Circuit 32

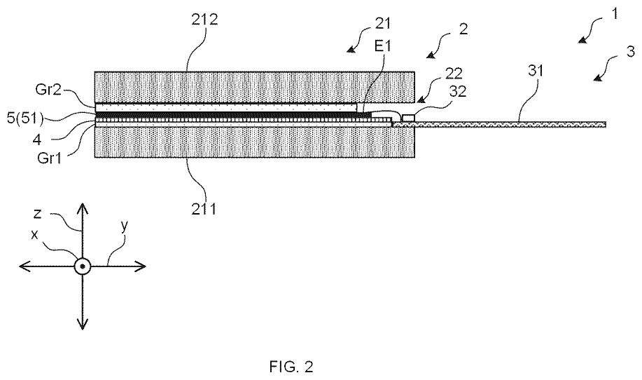

The integrated circuit 32 is configured to perform predetermined signal processing on the basis of at least the electromotive force outputted from a thermoelectric conversion 51 (see FIG. 2). The integrated circuit 32 is electrically connected to the heat flow sensor 22 and thus is configured to acquire the electromotive force. Such a configuration allows the measuring system 1 to perform signal processing on the basis of the electromotive force. The integrated circuit 32 includes, for example, a communication unit, a storage unit, and a processor, and these components are electrically connected through a communication bus inside the integrated circuit 32.

While the communication unit preferably uses wired communication means such as USB, IEEE 1394, Thunderbolt®, or wired LAN network communication, it may use wireless LAN network communication, mobile communication such as 3G, LTE, or 5G, BLUETOOTH® communication, or the like as necessary. Preferably, the communication unit is able to use a set of these multiple communication means. That is, the integrated circuit 32 may transmit and receive various types of information to and from the outside through the communication unit and any network.

The storage unit is storing various types of information defined by the above description. The storage unit may be embodied, for example, as a storage device such as a solid-state drive (SSD) for storing various programs or the like related to the measuring system 1 executed by the processor, or as memory such as random access memory (RAM) for storing temporarily required information (arguments, arrays, etc.) related to program calculations. The storage unit is storing various programs, variables, and the like related to the integrated circuit 32 executed by the processor.

The processor processes and controls overall operation related to the measuring system 1. For example, the processor is a central processing unit (CPU) (not shown). The processor implements various functions related to the measuring system 1 by reading a predetermined program stored in the storage unit. That is, when information processing by software stored in the storage unit is specifically executed by the processor, which is an example of hardware, functional units included in the processor are implemented. These will be described in more detail in the next section. Note that the processor does not have to be a single processor but may include function-specific multiple processors. Or, the processor may be a combination of these. The integrated circuit 32 may consist of the processor alone. The integrated circuit 32 does not have to be a digital circuit including the processor but may be an analog circuit.

### 1.2. Details of Measuring System 1

This section describes details of the measuring system 1 described in the previous section. FIG. 2 is a cross-sectional view of a surface having the x-axis direction as the normal direction of the measuring system 1 shown in FIG. 1.

As shown in FIG. 2, housing 21 includes a first wall 211 and a second wall 212. The first wall 211 and second wall 212 extend in the shape of a plate in an xy plane. For convenience's sake, it is assumed that the first wall 211 and second wall 212 have the same shape. The first wall 211 and second wall 212 are disposed to be spaced from each other in the z-axis direction and face each other. At least a portion of the outer edge of the first wall 211 and at least a portion of the outer edge of the second wall 212 are connected through a peripheral wall (not shown). Thus, an area that can house the heat flow sensor 22 is formed between the first wall 211 and the second wall 212.

### Heat Flow Sensor 22

The heat flow sensor 22 is configured to exchange heat with an object to be measured (not shown) through the housing 21. The heat flow sensor 22 includes a substrate 4 and a thermoelectric conversion device 5.

The substrate 4 has electrical insulation properties. Preferably, the substrate 4 is rigid against an external force along the z-axis direction in terms of the durability in the housing 21. In the present embodiment, the substrate 4 is formed as a flat plate having the z-axis direction as the normal direction. The substrate 4 may take any form. For example, the substrate 4 may be a chip that incorporates an LSI (large-scale integrated circuit) made of Si or the like, or may be an insulating film made of polyamide or the like, a flexible circuit board, a printed circuit board, a sapphire substrate, an Al board, a Cu board, an MgO board, or a substrate made of GaN, SiC, SiO₂/Si, Ta₂O₅/Ta, Al₂O₃, Al₂O₃/Al, SiN, Ti, TiO₂/Ti, CuO/Cu, Ga₂O₃, GaAs, InAs, InSb, or the like or a composite or the like thereof and having good thermal conductivity on which an IC is mounted, or may be any combination thereof.

### First Bonding Layer Gr1

The heat flow sensor 22 may further include a first bonding layer Gr1. The first bonding layer Gr1 bonds the substrate 4 to the first wall 211. Although the first bonding layer Gr1 may be made of any material, it is preferably made of a material having relatively low thermal resistance and heat capacity. In other words, the heat flow sensor 22 according to the present embodiment is formed by forming a heat flow sensor film (a circuit consisting of thermoelectric conversion elements 511, i.e., an example of the thermoelectric conversion unit 51) on a substrate and bonding the substrate to the housing 21 (in particular, the first wall 211). The top surface of the heat flow sensor film may also be bonded to the housing 21.

The thermoelectric conversion device 5 includes at least one (in the present embodiment, one) thermoelectric conversion unit 51. The thermoelectric conversion unit 51 is configured to generate an electromotive force on the basis of the temperature gradient along the z-axis direction. For example, the thermoelectric conversion unit 51 is configured to generate an electromotive force on the basis of the anomalous Nernst effect. Such a configuration makes the size of the measuring system 1 in the gradient direction more compact than that of measuring systems using Seebeck elements. Note that at least a portion of the thermoelectric conversion unit 51 may be configured to generate an electromotive force on the basis of the Seebeck effect.

The thermoelectric conversion unit 51 is disposed over the substrate 4 in the z-axis direction. The z-axis direction is an example of the gradient direction due to it being a direction from the substrate 4 toward the thermoelectric conversion unit 51. Specifically, the thermoelectric conversion unit 51 is disposed on a surface opposite to a surface connected to the first wall 211 of the substrate 4. Thus, the first wall 211 is configured to exchange heat with the thermoelectric conversion unit 51 through the substrate 4.

The thermoelectric conversion unit 51 is connected to the second wall 212 by a second bonding layer Gr2 not through the substrate 4 or an insulating rigid member different from the substrate 4. The second bonding layer Gr2 is made of a material similar to that of the first bonding layer Gr1. The second wall 212 is thus configured to exchange heat with the thermoelectric conversion unit 51 not through the substrate 4 or a substrate different from the substrate 4. Such a configuration makes the size of the measuring system 1 in the gradient direction more compact than that of conventional arts. An area facing the second wall 212 of the thermoelectric conversion unit 51, in other words, an area to which the second bonding layer Gr2 is bonded may be electrically insulated from the second wall 212 by stacking an insulating film on the area. In other words, a member that is not rigid but has electrical insulating properties may be interposed between the thermoelectric conversion unit 51 and the second wall 212.

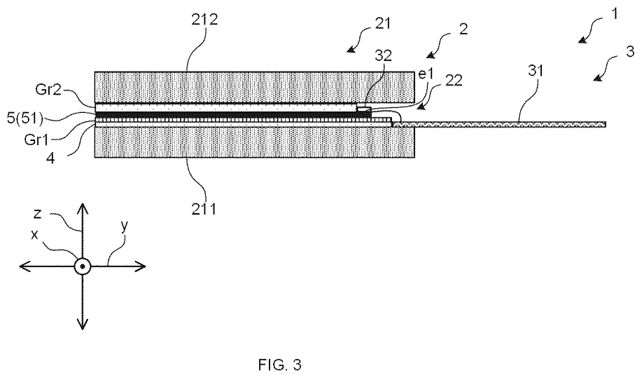

The heat flow sensor 22 may include an exposed portion E1 that faces the second wall 212 with a space therebetween at least in the gradient direction. For example, the exposed portion El may be formed by exposing at least a portion of the area facing the second wall 212 of the thermoelectric conversion unit 51 to the second wall 212. Various devices can be disposed on the exposed area E1. Thus, the internal space of the housing 21 can be used more efficiently. FIG. 3 is a diagram showing an example configuration of the measuring system 1 where the integrated circuit 32 as an example of a device is disposed on the exposed portion E1. As shown in FIG. 3, the integrated circuit 32 as an example of a device may be disposed on the exposed portion El so as to face the second wall 212 at least in the gradient direction. Such a configuration reduces the possibility that the integrated circuit can interfere with an external object compared to when the integrated circuit is located outside the housing 21.

### 1.3.1 Details of Thermoelectric Conversion Unit 51

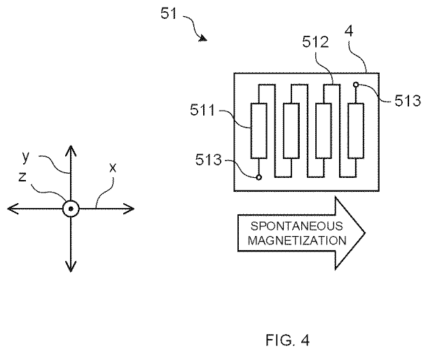

An example configuration of a single thermoelectric conversion unit 51 will be described below. FIG. 4 is a diagram showing an example configuration of the thermoelectric conversion unit 51. As shown in FIG. 4, the thermoelectric conversion unit 51 includes multiple thermoelectric conversion elements 511, wiring 512, and a pair of output terminals 513.

### Thermoelectric Conversion Element 511

The thermoelectric conversion elements 511 are each configured to generate an electromotive force due to the temperature gradient (in other words, heat transfer) in the z-axis direction on the basis of a thermoelectric effect. The thermoelectric conversion elements 511 extend along the y-axis direction. The thermoelectric conversion elements 511 are spontaneously magnetized in a direction (in the present embodiment, the x-axis direction) different from the z-axis direction as the gradient direction and thus are each configured to generate an electromotive force in an in-plane direction due to the above temperature gradient. For example, the thermoelectric conversion elements 511 may be formed as thin films. The thermoelectric conversion unit 51 may include a magnetic domain configured to be magnetized along the x-axis direction, which is one of the in-plane directions of the thin films. The thermoelectric conversion elements 511 may be formed in bulk. The material of the thermoelectric conversion elements 511 may be, for example, a topological ferromagnetic or topological antiferromagnetic material called Weyl semimetal, a ferrimagnetic material, or a combination of these. These specific materials will be described later.

### Wiring 512

The wiring 512 connects multiple thermoelectric conversion elements 511 in series such that the polarities thereof are aligned.

### Output Terminal 513

The output terminals 513 are terminals configured to output the total value of the electromotive forces outputted from the whole thermoelectric conversion elements 511. The output terminals 513 do not have to be mounted as actual connection terminals but may be virtual terminals connected to an external device. In the present embodiment, the thermoelectric conversion unit 51 includes a pair of output terminals 513, and the total electromotive force V1, which is the total value of the electromotive forces of the thermoelectric conversion elements 511, is outputted from the pair of output terminals 513. In the present embodiment, the thermoelectric conversion unit 51 outputs the total electromotive force V1 based on a heat flow associated with the temperature gradient from the output terminals 513. Ideally, V1=n×k×M×Q (where k represents a proportional constant, M represents the magnetization of the thermoelectric conversion elements 511, Q represents the amount of heat transferred, and n represents the number of thermoelectric conversion elements 511 connected in series). The direction of heat transfer corresponds to the temperature gradient. The thermoelectric conversion elements 511 included in one thermoelectric conversion unit 51 have the same polarity.

### 2. Example Configuration of Thermoelectric Conversion Device 5 Including Multiple Thermoelectric Conversion Units 51

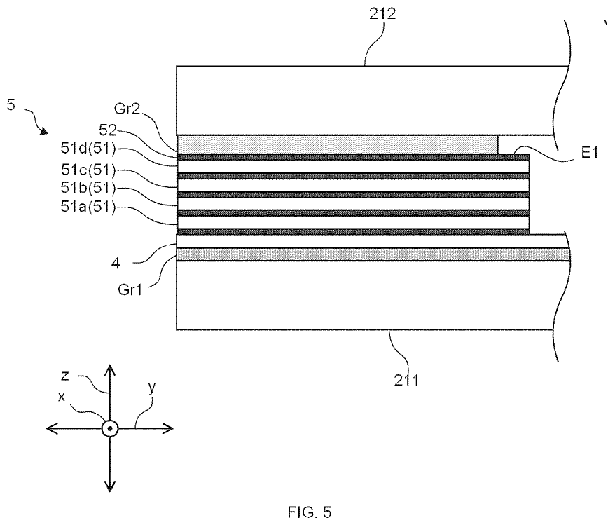

This section describes an example configuration of a thermoelectric conversion device 5 including multiple thermoelectric conversion units 51. FIG. 5 is a diagram showing an example configuration of the thermoelectric conversion device 5 including multiple thermoelectric conversion units 51. The same components as the above components are given the same numbers and the description thereof may be omitted.

As shown in FIG. 5, in the present embodiment, the thermoelectric conversion device 5 includes four thermoelectric conversion units 51a to 51d as multiple thermoelectric conversion units 51 and insulating films 52 having electrical insulation properties. As with the above thermoelectric conversion unit 51 described with reference to FIG. 4, the thermoelectric conversion units 51a to 51d each include multiple thermoelectric conversion elements 511, wiring 512, and output terminals 513. The thermoelectric conversion units 51a to 51d are sequentially layered on the substrate 4 in the z-axis direction, starting with the thermoelectric conversion unit 51a. The thermoelectric conversion unit 51a is connected to the substrate 4, and the thermoelectric conversion unit 51d is connected to the second wall 212 through the second bonding layer Gr2. Thus, the four thermoelectric conversion units 51a to 51d form a multilayer body. In other words, the measuring system 1 further includes the multilayer body. The multilayer body is formed by layering multiple thermoelectric conversion elements 511 on the substrate 4 in the gradient direction. Such a configuration makes the size of the measuring system 1 in the in-plane direction smaller. Almost the same heat flow passes through the thermoelectric conversion units 51a to 51d forming the multilayer body.

In the present embodiment, the thermoelectric conversion elements 511 included in the thermoelectric conversion units 51a and 51c extend along the x-axis direction and are spontaneously magnetized in the y-axis direction. The thermoelectric conversion elements 511 of the thermoelectric conversion unit 51a and the thermoelectric conversion elements 511 of the thermoelectric conversion unit 51c are configured such that the directions of spontaneous magnetization thereof are opposite (e.g., anti-parallel). Thus, the thermoelectric conversion unit 51a and thermoelectric conversion unit 51c have opposite polarities. This allows the thermoelectric conversion units 51a and 51c to output electromotive forces in opposite directions on the basis of the same temperature gradient in the z-axis direction. The thermoelectric conversion units 51a and 51c are examples of first thermoelectric conversion elements, and the y-axis direction is an example of a first output direction. In other words, the multiple first thermoelectric conversion elements are each configured to output an electromotive force along the first output direction, which is one of the in-plane directions of the substrate 4, on the basis of the temperature gradient. The polarity of at least one of the first thermoelectric conversion elements is different from the polarity of at least one of the first thermoelectric conversion elements. Such a configuration, for example, eliminates the effect of an electromotive force based on a temperature gradient in the in-plane direction, thereby making the measuring system 1 more accurate.

In the present embodiment, the thermoelectric conversion elements 511 included in the thermoelectric conversion units 51b and 51d extend along an in-plane direction different from that of the thermoelectric conversion elements 511 included in the thermoelectric conversion units 51a and 51c and, specifically, along the y-axis direction and are spontaneously magnetized in the x-axis direction. The thermoelectric conversion elements 511 of the thermoelectric conversion unit 51b and the thermoelectric conversion elements 511 of the thermoelectric conversion unit 51d are configured such that the directions of spontaneous magnetization thereof are opposite (e.g., anti-parallel). Thus, the thermoelectric conversion unit 51b and thermoelectric conversion unit 51d have opposite polarities. This allows the thermoelectric conversion units 51b and 51d to output electromotive forces in opposite directions on the basis of the same temperature gradient in the z-axis direction. The thermoelectric conversion elements 511 included in the thermoelectric conversion units 51b and 51d are an example of second thermoelectric conversion elements, and the x-axis direction is an example of a second output direction. In other words, the thermoelectric conversion units 51 include the multiple second thermoelectric conversion elements. The second thermoelectric conversion elements are each configured to output an electromotive force along the second output direction, which is one of the in-plane directions of the substrate 4 and is different from the first output direction, on the basis of the temperature gradient. The polarity of at least one of the second thermoelectric conversion elements is different from the polarity of at least one of the second thermoelectric conversion elements. Such a configuration reduces the effect of the temperature gradients in the multiple in-plane directions. It can also be understood that the thermoelectric conversion units 51a and 51b constitute one thermoelectric conversion section, the thermoelectric conversion units 51c and 51d constitute one thermoelectric conversion section, and these thermoelectric conversion sections have different polarities. The first output direction and second output direction may be any directions as long as they are each along one of the in-plane directions, and do not have to be perpendicular to the z-axis direction (in other words, the gradient direction). The first output direction and second output direction do not have to be perpendicular to each other as long as they intersect each other. The number of layered thermoelectric conversion units 51 does not have to be four.

### 3. Others

The measuring system 1 according to the above embodiment is not limiting. For example, the measuring system 1 according to the above embodiment can take the following aspects.

The integrated circuit 32 may be disposed on the substrate 4. The integrated circuit 32 may be disposed outside the housing 21.

Both the first wall 211 and second wall 212 may be stacked to be in close contact with the substrate 4 and thermoelectric conversion device 5.

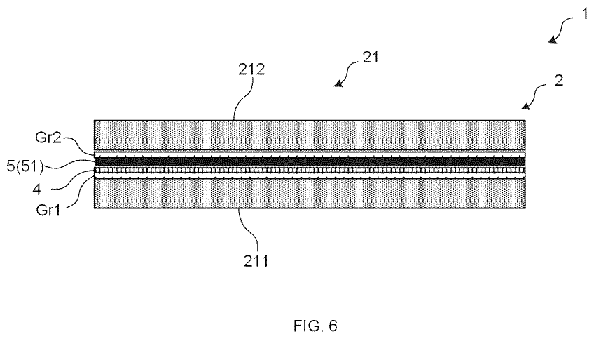

For example, the measuring system 1 does not have to include the signal processing unit 3. FIG. 6 is a diagram showing an example of a measuring system 1 without the signal processing unit 3. As shown in FIG. 6, for example, the measuring system 1 may include only the measuring unit 2. In this case, the thermoelectric conversion unit 51 of the measuring unit 2 does not have to include the exposed portion El but its entire surface may be bonded to the second wall 212. Such a configuration increases the area of the thermoelectric conversion unit with respect to the temperature gradient, thereby increasing the sensitivity of the measuring system 1 to temperature gradient.

The measuring system may be provided in aspects below.

(1) A measuring system comprising: a heat flow sensor including: a substrate including electrical insulation properties and a thermoelectric conversion unit disposed on the substrate; and a thermoelectric conversion unit configured to generate an electromotive force on the basis of a temperature gradient along a gradient direction that is a direction from the substrate toward the thermoelectric conversion unit, wherein: the housing houses the heat flow sensor and includes a first wall and a second wall, the first wall is configured to exchange heat with the thermoelectric conversion unit through the substrate, and the second wall is configured to exchange heat with the thermoelectric conversion unit not through the substrate or a substrate different from the substrate.

Such a configuration makes the size of the measuring system in the gradient direction more compact than that of conventional arts.

(2) The measuring system according to (1), wherein: the thermoelectric conversion unit includes a plurality of first thermoelectric conversion elements, the first thermoelectric conversion elements are each configured to output the electromotive force along a first output direction on the basis of the temperature gradient, the first output direction being one of in-plane directions of the substrate, and a polarity of at least one of the first thermoelectric conversion elements is different from a polarity of at least one of the first thermoelectric conversion elements.

Such a configuration, for example, eliminates the effect of an electromotive force based on a temperature gradient in the in-plane direction, thereby making the measuring system more accurate.

(3) The measuring system according to (2), further comprising: a multilayer body formed by layering the first thermoelectric conversion elements on the substrate in the gradient direction.

Such a configuration makes the size of the measuring system in the in-plane direction smaller.

(4) The measuring system according to (2) or (3), wherein: the thermoelectric conversion unit includes a plurality of second thermoelectric conversion elements, the second thermoelectric conversion elements are each configured to output the electromotive force along a second output direction on the basis of the temperature gradient, the second output direction being one of the in-plane directions of the substrate and being different from the first output direction, and a polarity of at least one of the second thermoelectric conversion elements is different from a polarity of at least one of the second thermoelectric conversion elements.

Such a configuration reduces the effect of the temperature gradients in the multiple in-plane directions.

(5) The measuring system according to any one of (1) to (4), further comprising an integrated circuit configured to acquire the electromotive force, the integrated circuit being configured to perform predetermined signal processing on the basis of at least the electromotive force outputted from the thermoelectric conversion unit.

Such a configuration allows the measuring system to perform signal processing on the basis of the electromotive force.

(6) The measuring system according to (5), wherein the integrated circuit is disposed on the substrate so as to be housed in the housing.

Such a configuration reduces the possibility that the integrated circuit can interfere with an external object compared to when the integrated circuit is located outside the housing.

(7) The measuring system according to any one of (1) to (6), wherein the thermoelectric conversion unit is configured to generate the electromotive force on the basis of the anomalous Nernst effect.

Such a configuration makes the size of the measuring system in the gradient direction more compact than that of measuring systems using Seebeck elements.

Of course, these aspects are not limiting.

Finally, while the various embodiments according to the present disclosure have been described above, the embodiments are only illustrative and are not intended to limit the scope of the invention. The novel embodiments can be carried out in other various forms, and various omissions, replacements, or changes can be made thereto without departing from the gist of the invention. The embodiments and modifications thereof are included in the scope and gist of the present invention, as well as included in the scope of the invention set forth in the claims and equivalents thereof.

The following aspects should also be noted.

Conventional heat flux sensors are heat flux sensors using the Seebeck effect. The housing of such sensors using the Seebeck effect is formed to be sturdy for protection but has large heat capacity and thermal resistance. These sensors having large thermal resistance and heat capacity block the heat flow path and therefore have difficulty in correctly measuring the heat flow.

For this reason, in a device according to the present embodiment and a system using the device, for example, a heat flow sensor film having high thermal conductivity that generates the anomalous Nernst effect is disposed on a substrate having good thermal conductivity, and the sensor substrate is housed in a housing having high insulation properties and thermal conductivity. Such a configuration allows for more correct measurement of the heat flow.

The heat flow sensor according to the present embodiment (an example of a device) is preferably a thin film-type heat flow sensor based on the anomalous Nernst effect in terms of the responsiveness. The elements (i.e., the thermoelectric conversion elements) of the heat flow sensor (i.e., the thermoelectric conversion device) may be made of a compound that exhibits the anomalous Nernst effect. For example, the elements may be made of a topological ferromagnetic material or topological antiferromagnetic material called Weyl semimetal, a ferrimagnetic material, or a combination thereof. The topological ferromagnetic material may be a metal with a composition Co₂TX (where X represents any one of Si, Ge, Sn, Al, and Ga), such as Co₂MnGa, or may be an alloy of a known topological ferromagnetic material, such as a metal with a composition formula Fₑ3X (where X represents a typical element such as Al or Ga, or a transition element) (a stoichiometric or off-stoichiometric composition). The topological antiferromagnetic material may be a known topological antiferromagnetic material, such as Mn₃X (where X represents one or more elements selected from Sn, Ge, Ga, Pt, Ir, and Rh, or a compound of these). The alloy containing the topological ferromagnetic material or topological antiferromagnetic material does not necessarily have to have a stoichiometric composition ratio as described above. The alloy may have any composition ratio as long as it has a partially stoichiometric structure. The compound constituting the elements may consist of, for example, an alloy containing a transition metal, and the alloy may be a compound that has a crystal structure with Kagome lattice planes made of a transition metal and exhibits the anomalous Nernst effect. The ferrimagnetic material may be any type of ferrimagnetic material as long as it generates the anomalous Nernst effect. The structure of the elements is not limited to a particular structure, and any known structure may be used. The elements may be formed by sputtering, evaporation, MBE, plating, sintering, printing, pasting, or the like. The heat flow sensor according to the present embodiment may be configured not only to measure heat, but also to detect light, a chemical, or the like.

In the heat flow sensor according to the present embodiment, the heat flow sensor film (a circuit consisting of the thermoelectric conversion elements) is formed on the substrate, and the substrate is bonded to the housing. The top surface of the heat flow sensor film may also be bonded to the housing. The material of a bonding film or the housing is preferably a material having relatively low thermal resistance and heat capacity. For example, the material of the housing may be a metal, carbon, or the like.

The heat flow sensor film may be a multilayer film, or may include a magnet layer (hard layer), or may include a coil layer, or may be a film formed by inserting an insulating layer and stacking a circuit of thermoelectric conversion elements, or may be any combination of these. To cancel out the Seebeck effect, which acts as the noise of the anomalous Nernst effect, multiple (preferably, four) heat flow sensors having different polarities may be formed on a plane or in the shape of a multilayer film. For example, the sum of signals A, B, C, and D shown in the diagrams cancels out the Seebeck effect so that the anomalous Nernst effect (a heat flow in the z-direction) can be extracted. A and D can detect a heat flow in the x-axis direction from the Seebeck effect, and C and B can detect a heat flow in the y-direction from the Seebeck effect. The order of the diagrams may be any order. A thin bonding layer may be provided between the sensor film and the substrate. The bonding layer may be made of any material as long as it has low thermal resistance. Preferably, the housing has low thermal resistance.

To make more accurate measurements, an IC for signal processing that includes an MUX, an amplifier, an ADC, a processor, a DSP, memory, a communication function, and the like may be provided. In this case, the substrate may be, for example, a chip that incorporates an LSI (large-scale integrated circuit) made of Si or the like, or may be an insulating film made of polyamide or the like, a flexible circuit board, a printed circuit board, a sapphire substrate, an Al board, a Cu board, an MgO board, or a substrate made of GaN, SiC, SiO₂/Si, Ta₂O₅/Ta, Al₂O₃, Al₂O₃/Al, SiN, Ti, TiO₂/Ti, CuO/Cu, Ga₂O₃, GaAs, InAs, InGaAs, InSb, or the like or a composite or the like thereof and having good thermal conductivity on which an IC is mounted, or may be any combination thereof. The terminals may be disposed on a flexible board. These structures are not limiting.

An opening may be formed in an upper portion or lower portion of the heat flow sensor so that the heat flow sensor communicates with the outside and thus the thermal resistance is reduced. The opening may be a physical opening, or the heat flow sensor may be connected to a member having low thermal resistance. The PKG (package) of the IC may be a PKG shown in the diagram or a package such as a WLCSP.

A modification of the present embodiment will be described. For example, by providing a film or the like capable of absorbing electromagnetic radiation such as light on the heat flow sensor, electromagnetic radiation may be detected. By further providing an optical filter, only electromagnetic radiation (light) in a selected wavelength band may be detected. Thus, the selectivity can be increased. Moreover, by applying or providing a substance that reacts to or adsorbs a gas, liquid, or solution on the heat flow sensor, the gas or the like that reacts with the substance can be detected. If the above substance is thermally coupled to the heat flow sensor, it does not have to be provided directly on the heat flow sensor.

Another modification of the present embodiment will be described. A coil for generating a magnetic field for modulating the heat flow sensor or heat for heating the catalyst may be disposed inside the LSI or in any other layer. Since such a coil transmits heat, there is no problem in making measurements. The coil may be disposed in any position as long as the position has good heat conductivity. The application of the heat flow sensor is not limited to a particular application. The heat flow sensor only has to be a heat flow sensor based on the anomalous Nernst effect and does not have to detect electromagnetic radiation or substance.

1. A measuring system comprising:
a heat flow sensor including:
a substrate including electrical insulation properties and
a thermoelectric conversion unit disposed on the substrate; and
a thermoelectric conversion unit, implemented by circuitry, configured to generate an electromotive force on the basis of a temperature gradient along a gradient direction that is a direction from the substrate toward the thermoelectric conversion unit, wherein:
the housing houses the heat flow sensor and includes a first wall and a second wall,
the first wall is configured to exchange heat with the thermoelectric conversion unit through the substrate, and
the second wall is configured to exchange heat with the thermoelectric conversion unit not through the substrate or a substrate different from the substrate.

2. The measuring system according to claim 1, wherein:
the thermoelectric conversion unit includes a plurality of first thermoelectric conversion elements,
the first thermoelectric conversion elements are each configured to output the electromotive force along a first output direction on the basis of the temperature gradient, the first output direction being one of in-plane directions of the substrate, and
a polarity of at least one of the first thermoelectric conversion elements is different from a polarity of at least one of the first thermoelectric conversion elements.

3. The measuring system according to claim 2, further comprising:
a multilayer body formed by layering the first thermoelectric conversion elements on the substrate in the gradient direction.

4. The measuring system according to claim 2, wherein:
the thermoelectric conversion unit includes a plurality of second thermoelectric conversion elements,
the second thermoelectric conversion elements are each configured to output the electromotive force along a second output direction on the basis of the temperature gradient, the second output direction being one of the in-plane directions of the substrate and being different from the first output direction, and
a polarity of at least one of the second thermoelectric conversion elements is different from a polarity of at least one of the second thermoelectric conversion elements.

5. The measuring system according to claim 1, further comprising
an integrated circuit configured to acquire the electromotive force,
the integrated circuit being configured to perform predetermined signal processing on the basis of at least the electromotive force outputted from the thermoelectric conversion unit.

6. The measuring system according to claim 5, wherein
the integrated circuit is disposed on the substrate so as to be housed in the housing.

7. The measuring system according to claim 1, wherein
the thermoelectric conversion unit is configured to generate the electromotive force on the basis of the anomalous Nernst effect.
